(19) United States
(12) Patent Application Publication
(10) Pub. No.: US 2012/0205696 A1
(43) Pub. Date: Aug. 16, 2012

(54) LIGHT EMITTING DEVICE PACKAGE AND METHOD OF MANUFACTURING THEREOF

(76) Inventors: Cheol Jun YOO, Cheonan (KR); Young Hee Song, Seongnam (KR); Seong Deok Hwang, Seoul (KR); Sang Hyun Lee, Suwon (KR)

(21) Appl. No.: 13/356,245

(22) Filed: Jan. 23, 2012

(30) Foreign Application Priority Data
Feb. 15, 2011 (KR) 10-2011-0013385

(51) Int. Cl. H01L 33/50; H01L 33/58; H01L 33/62

(52) U.S. Cl. 257/98; 438/27; 257/E33.061; 257/E33.066; 257/E33.073

(57) ABSTRACT

There are provided a light emitting device package and a method of manufacturing thereof. The light emitting device package including a first lead frame including amounting area and a heat radiating area surrounding the mounting area, the mounting area being protruded upwardly so as to be located higher than the heat radiating area; a second lead frame disposed to be spaced apart from the first lead frame; at least one light emitting device disposed on the mounting area of the first lead frame; a molding part formed so as to fix the first and second lead frame leads thereto; and a lens part disposed over the at least one light emitting device and the molding part, and the method of manufacturing the light emitting device package are provided.

### CROSS-REFERENCE TO RELATED APPLICATIONS

This application claims the priority of Korean Patent Application No. 10-2011-0013385 filed on Feb. 15, 2011, in the Korean Intellectual Property Office, the disclosure of which is incorporated herein by reference.

### BACKGROUND OF THE INVENTION

1. Field of the Invention

The present invention relates to a light emitting device package and a method of manufacturing thereof.

2. Description of the Related Art

In general, a luminous element is an element used to transmit a signal generated by converting electrical energy into infrared or visible rays. A light emitting diode (LED) is a kind of electroluminescence (EL) device, and currently, a light emitting diode using a group III-V compound semiconductor has been in practical use. A group III nitride compound semiconductor is a direct transition semiconductor, and may be stably operated at a high temperature, as compared to another semiconductor, and has therefore been widely applied to a luminous element, such as a light emitting diode or a laser diode.

In general, the light emitting device may constitute a light emitting device package, and the light emitting device package maybe mounted on a substrate. The light emitting device package may include a package body having a shape exposing the light emitting device and made of a resin. Thus, the package body is formed by molding a resin composition having superior lightfastness and transmittance, and in this case, the discoloration of the resin due to a high temperature generated during the operation of the light emitting device may act as amain cause of the degradation of luminance. In addition, since the light emitting device package may require a separate heat radiating member attached thereto in order to solve the defect, there are difficulties in terms of cost and methods of manufacturing thereof.

### SUMMARY OF THE INVENTION

An aspect of the present invention provides a semiconductor light emitting device having improved reliability through the application of a high functional molding material having high adhesion, high reliability, high heat-resistant properties, high flame retardancy, and excellent mechanical properties.

An aspect of the present invention also provides a method of manufacturing a semiconductor light emitting device having a superior heat radiating function through a simple process to thereby allow for improvements in reliability.

According to an aspect of the present invention, there is provided a lighting emitting device package, including: a first lead frame including amounting area and a heat radiating area surrounding the mounting area, the mounting area being protruded upwardly so as to be located higher than the heat radiating area; a second lead frame disposed to be spaced apart from the first lead frame; at least one light emitting device disposed on the mounting area of the first lead frame; a molding part formed so as to fix the first and second lead frame leads thereto; and a lens part disposed over the at least one light emitting device and the molding part.

The molding part may be formed on upper surfaces of the first and second lead frames, such that an upper surface of the molding part is located lower than an upper surface of the at least one light emitting device.

The molding part may be formed to cover a region of a lower surface of the first lead frame corresponding to the mounting area.

The molding part may be made of a material different from that of the lens part.

The molding part is made of a colored resin.

The first lead frame may include a mounting area upwardly protruded and having a quadrangular shape, and the heat radiating area of the first lead frame and the second lead frame may be coplanarly located.

At least one of the first and second lead frames may have at least a part of a lower surface exposed to the outside.

The molding part may be formed such that at least parts of upper surfaces of the first and second lead frames are exposed, and the first and second lead frames may be wire-bonded to the at least one light emitting device through the exposed surfaces thereof.

At least one of the first and second lead frames may include a through hole formed therein.

The lighting emitting device package may further include a groove formed by removing a part of the first lead frame in a direction from a side of the first lead frame to the mounting area.

The groove may be formed in the side of the first lead frame, opposite to the second lead frame.

The lighting emitting device package may further include a phosphor layer formed in at least a part of a light emitting surface of the at least one light emitting device. According to another aspect of the present invention, there is provided a method of manufacuring a light emitting device package, the method including: press processing at least one of first and second lead frames such that the at least one of first and second lead frames has amounting area and a heat radiating area surrounding the mounting area formed thereon, the mounting area being protruded upwardly so as to be located higher than the heat radiating area; forming a molding part in a space between the first and the second lead frames spaced apart from each other to thereby fix the first and the second lead frames thereto; disposing at least one light emitting device on the mounting area; and disposing a lens part over the at least one light emitting device.

At least one of the first and second lead frames may have at least a part of a lower surface exposed to the outside.

The molding part may be formed on upper surfaces of the first and second lead frames, such that an upper surface of the molding part is located lower than an upper surface of the at least one light emitting device.

The molding part may be formed to cover a region of a lower surface of the first lead frame, corresponding to the mounting area.

The molding part may be made of a colored resin.

The method may further include wire-bonding the at least one light emitting device to at least one of the first and second lead frames.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a light emitting device package according to an embodiment of the present invention;

FIGS. 2A and 2B are schematic views of first and second lead frames according to the embodiment shown in FIG. 1, when viewed from above;

FIG. 3 is a schematic view of a light emitting device package according to another embodiment of the present invention, when viewed from above; and

FIGS. 4 through 8 are diagrams schematically showing a method of manufacturing the light emitting device package according to the embodiment of the present invention.

### DETAILED DESCRIPTION OF THE INVENTION

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and sizes of components are exaggerated for clarity. The same or equivalent elements are referred to by the same reference numerals throughout the specification.

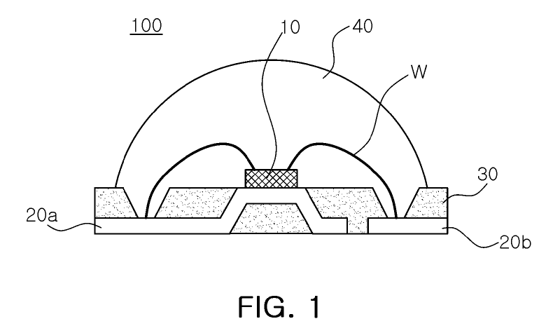

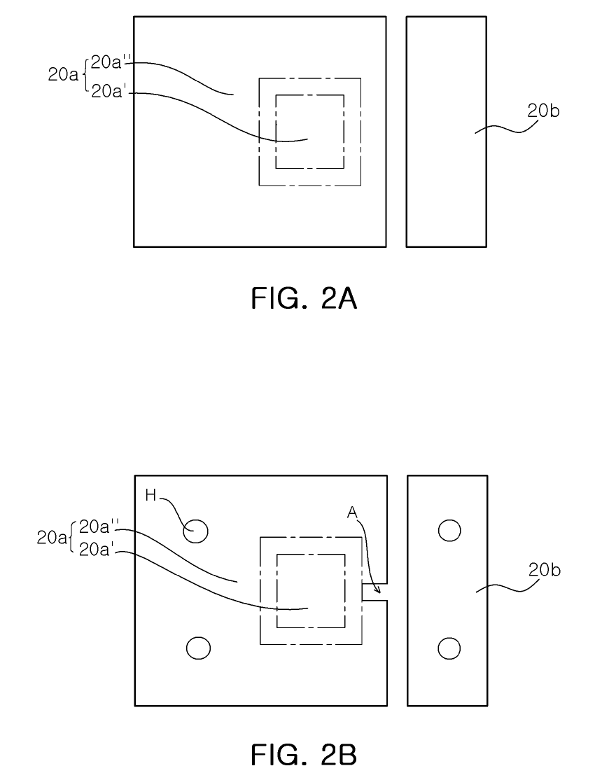

FIG. 1 is a schematic cross-sectional view of a light emitting device package according to an embodiment of the present invention. FIGS. 2A and 2B are schematic views of first and second lead frames according to the embodiment shown in FIG. 1, when viewed from above. Referring to FIG. 1, a light emitting device package 100 according to an embodiment of the present invention may include a first lead frame 20a including a mounting area 20a′ and a heat radiating area 20a″ surrounding the mounting area 20a′, the mounting area 20a′ being protruded upwardly so as to be located higher than the heat radiating area 20a″, a second lead frame 20b disposed to be spaced apart from the first lead frame 20a, at least one light emitting device 10 disposed on the mounting area 20a′ of the first lead frame 20a, a molding part 30 formed in a space between the first and second lead frames 20a and 20b so as to fix the first and second lead frame leads 20a and 20b thereto, and a lens part 40 disposed over the light emitting device 10 and the molding part 30.

Any optoelectronic device capable of emitting light when an electrical signal is applied thereto may be used as the light emitting device 10. Representatively, a semiconductor light emitting device in which a semiconductor layer is epitaxially grown on a growth substrate may be used. The growth substrate may be made of sapphire; however, it is not limited thereto. The growth substrate may be made of a substrate material well known in the art, such as spinel, silicon carbide (SiC), gallium nitride (GaN), gallium arsenide (GaAs) or the like. In particular, the light emitting device 10 may be made of BN, SiC, ZnSe, GaN, InGaN, InAlGaN, AlGaN, BAlGaN, BInAlGaN or the like, and may be doped with Si, Zn or the like. In addition, a light emitting layer of the light emitting device 10 may be made of a nitride semiconductor formed of InₓAl_{y}Ga_{1-x-y} (0≦x≦1, 0≦y≦1, x+y≦1), and may have a single or multiple quantum well structure, whereby the output thereof may be improved.

As shown in FIG. 1, electrodes (not shown) formed on an upper surface of the light emitting device 10 may be wire-bonded to the first and second lead frames 20a and 20b, to be supplied with an external electrical signal applied thereto. The embodiment of the present invention illustrates that the light emitting device 10 may be wire-bonded to each of the first and second lead frames 20a and 20b through the electrodes formed thereon; however, the concrete connection method thereof may be variously modified as needed, such as a direct wireless electrical connection to the first lead frame 20a provided as the mounting area of the light emitting device 10 while being connected to the second lead frame 20b through a conductive wire, or the like. In addition, the embodiment of the present invention illustrates one light emitting device 10 within the light emitting device package 10; however, two or more light emitting devices 10 may be disposed on the first lead frame 20a.

The first and second lead frames 20a and 20b may be provided as the mounting area of the light emitting device 10, and at the same time, may function as a terminal applying an electrical signal supplied from the outside to the light emitting device 10. In order to function as the terminal, a pair of the lead frames 20a and 20b may be made of a metallic material having excellent electrical conductivity. Specifically, referring to FIG. 2A, the first lead frame 20a may include the mounting area 20a′ and the heat radiating area 20a″ surrounding the mounting area 20a′, and here, the mounting area 20a′ may be upwardly protruded so as to be located higher than the heat radiating area 20a″ and may have at least one light emitting device 10 disposed thereon. The mounting area 20a′ of the first lead frame 20a may be formed such that only a partial area inside the first lead frame 20a, rather than the outside portion thereof, may be upwardly protruded, whereby the heat radiating area 20a″ surrounding the mounting area 20a′ may be disposed to be exposed to the outside on a side opposite to that of the mounting area of the light emitting device 10.

According to the embodiment, the majority of the lower surfaces of the first and second lead frames 20a and 20b may be exposed to the outside to thereby directly come into contact with a substrate for mounting the light emitting device package 100, whereby limitations regarding the radiation of heat, caused by the mounting area 20a′ of the light emitting device 10 being upwardly protruded, may be solved. Specifically, the first lead frame 20a may include the mounting area 20′ upwardly protruded and having a quadrangular shape. The heat radiating area 20a″ of the first lead frame 20a surrounding the mounting area 20′ and the second lead frame 20b are coplanarly located, and at least parts of the lower surfaces of the first and second lead frames 20a and 20b may be exposed to the outside. The exposed surfaces of the first and second lead frames 20a and 20b may be disposed so as to come into direct contact with a substrate, for example, a printed circuit board (PCB) made of an organic resin material containing epoxy, triazine, silicon, polyimide or the like and other organic resin materials, or made of a ceramic material, such as AIN, Al₂O₃ or the like or a metallic material and a metal compound material, and may effectively transmit heat emitted from the light emitting device 10 to the outside.

FIG. 2B is a modified example of lead frames applicable to a light emitting device package according to an embodiment of the present invention. Referring to FIG. 2B, the lead frames may further include a groove A formed by removing a part of the first lead frame 20a in a direction from a side of the first lead frame 20a to the mounting area 20a′, unlike in the embodiment shown in FIG. 2A. The groove can be formed in a side of the first lead frame, opposite to the second lead frame. The groove A may allow a molding material to be easily filled in a lower portion of the mounting area 20a′ of the first lead frame 20a, in a molding process for the fixation of the first and second lead frames 20a and 20b, and allow for a broaden bonding area between the first lead frame 20a and the molding part 30 to thereby enhance adhesive strength. Meanwhile, the first and second lead frames 20a and 20b may include a plurality of through holes H to thereby allow for the disposition of the molding material on the upper and lower surfaces of the first and second lead frames 20a and 20b.

The molding material 30 formed in the space between the first and second lead frames 20a and 20b to fix the pair of lead frames thereto, may be formed on the first and second lead frames 20a and 20b such that an upper surface of the molding part is located lower than an upper surface of the at least one light emitting device 10. Referring to FIG. 1, the molding part 30 may be formed such that parts of the upper surfaces of the first and second lead frames 20a and 20b are exposed. The molding part 30 may also be formed so as to cover a region of the lower surface of the first lead frame 20a corresponding to the mounting area 20a′. In addition, the molding part 30 may be formed such that at least parts of the upper surfaces of the first and second lead frames 20a and 20b are exposed, and the first and second lead frames 20a and 20b may be wire-bonded to the light emitting device 10 through the exposed surfaces thereof.

Since the molding part 30 may be formed to be located lower than the upper surface of the light emitting device 10 and may not need to upwardly reflect light emitted from the light emitting device 10, applying a white or transparent molding material generally used in a light emitting device package to the molding part 30 may not be required. That is, according to the related art, as the molding part may be formed to enclose side surfaces of the light emitting device, the use of a white molding material having a light reflex function may be required so as to reflect light emitted from the side surfaces and lower surface of the light emitting device and to guide the emitted light in an upward direction. However, according to the present invention, since the molding part 30 maybe formed to be located lower than the upper surface of the light emitting device 10 and may not need to have the light reflex function, degradations in luminance caused by the discoloration of the white molding material due to a high temperature maybe prevented. Furthermore, a colored molding material having high adhesion, high reliability, high heat-resistant properties, high flame retardancy, and excellent mechanical properties, for example, a molding material having an epoxy molding compound (EMC) and various colors added therein, may be used.

Meanwhile, although not specifically illustrated, a phosphor layer (not shown) including a fluorescent substance for wavelength conversion may be formed on at least a part of the light emitting surface of the light emitting device 10. The phosphor layer may include phosphor particles for wavelength conversion, converting the wavelength of light emitted from an active layer of the light emitting device 10. The fluorescent substance may be made of a material converting the wavelength of light into a wavelength of any one of yellow, red, and green light, and the types of the fluorescent substance may be determined by the wavelength of light emitted from the active layer of the light emitting device 10. Concretely, the phosphor layer may include any one among a YAG based-, a TAG based-, a silicate based-, a sulfide based- and a nitride based fluorescent materials. For example, when a fluorescent substance converting the wavelength of light into a yellow light wavelength is applied to an LED chip emitting blue light, a semiconductor light emitting device emitting white color may be obtained.

The lens part 40 may be disposed on the light emitting device 10. Specifically, various shaped-lens, for example, a hemispherical shaped-transparent lens may be molded by disposing the light emitting device 10 on the first lead frame 20a, and then dispensing a resin to or molding the upper surface of the light emitting device 10 with a resin, whereby light extraction efficiency may be improved. The lens part 40 may protect the light emitting device 10 by entirely covering the light emitting device 10 and allow for the increase of light extraction by reducing a Fresnel reflection at an interface between the air and the lens part, due to the hemispherical shape thereof. In this case, the lens part 40 may be made of a resin, and the resin may include any one of epoxy, silicon, strained silicon, a urethane resin, an oxetane resin, acryl, polycarbonate, and polyimide. In addition, prominences and depressions may be formed on the upper surface of the lens part to thereby allow for the increase of light extraction efficiency and the adjustment of the direction of emitted light. The lens part 40 may be made of a material different from that of the molding material 30, and for example, the lens part 40 may be made of a transparent resin so as to allow for the efficient transmission of light and molding part 30 may be made of a high functional colored resin; however, the present invention is not limited thereto.

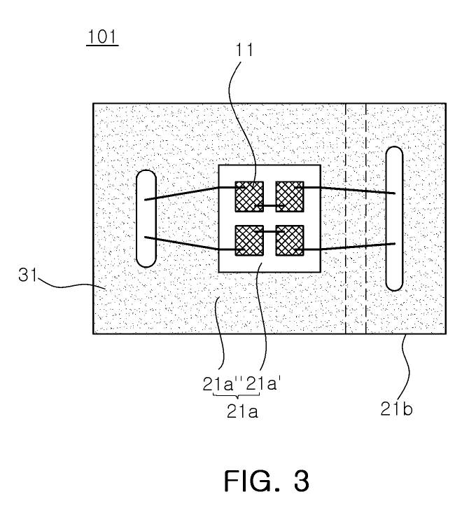

FIG. 3 is a schematic view of a light emitting device package according to another embodiment of the present invention, when viewed from above. A light emitting device package 101 according to another embodiment of the present invention may include a first lead frame 21a including a mounting area 21a′ and a heat radiating area 21a″ surrounding the mounting area 21a′, the mounting area 21a′ being protruded upwardly so as to be located higher than the heat radiating area 21a″, a second lead frame 21b disposed to be spaced apart from the first lead frame 21a, and a plurality of light emitting devices 11 disposed on the mounting area 21a′ of the first lead frame 21a. In FIG. 3, a lens part (not shown) disposed on the upper surfaces of the light emitting devices and a molding part may be omitted, and the embodiment of FIG. 3 may be different from the foregoing embodiment of FIG. 1 in that the plurality of light emitting devices 11 are disposed on the mounting area 21a′ of the first lead frame 21a.

Referring to FIG. 3, four light emitting devices 11 may be disposed on the mounting area 21a′ of the first lead frame 21a, and the light emitting devices 11 maybe connected in series and in parallel. The first and second lead frames 21a and 21b may be spaced apart by a predetermined distance so as to be electrically isolated from each other and may have a molding part 31 formed therebetween and on the upper surfaces thereof. The molding part 30 may be formed such that at least parts of the upper surfaces of the first and second lead frames 21a and 21b are exposed, and the first and second lead frames 21a and 21b may be individually wire-bonded to the light emitting devices 11 through the exposed surfaces thereof. However, as above mentioned, the electrical connection form of the light emitting devices 11 may be variously modified as needed, such as a direct electrical connection to the first lead frame 21a on which the light emitting devices 11 are mounted while being wire-bonded to the second lead frame 21b, or the like.

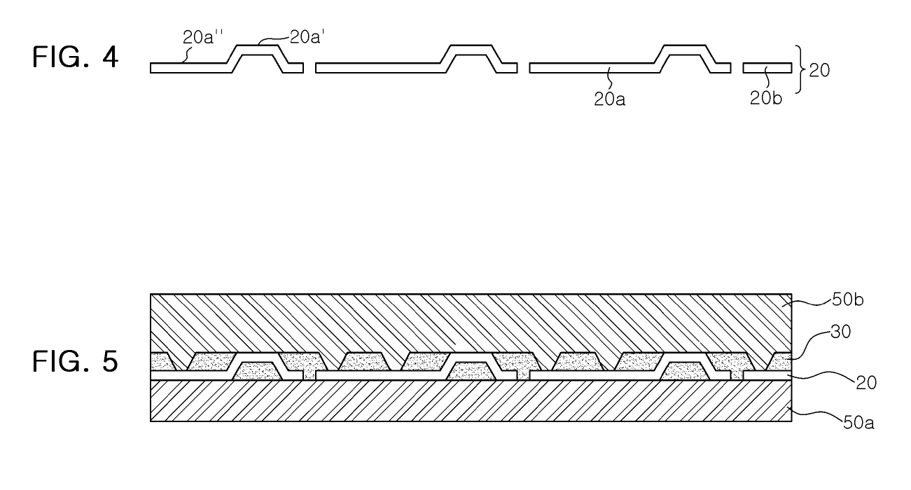

FIGS. 4 through 8 are diagrams schematically showing a method of manufacturing the light emitting device package according to the embodiment of the present invention. In concrete, FIGS. 4 through 8 are cross-sectional views of a process for manufacturing the light emitting device package 100 according to the embodiment shown in FIG. 1 Referring to FIG. 4, at least one of the first and second lead frames 20a and 20b may be subjected to press processing such that it may have the mounting area 20a′ and the heat radiating area 20a″ surrounding the mounting area 20a′ formed thereon, the mounting area 20a′ being protruded upwardly so as to be located higher than the heat radiating area 20a″. In the embodiment of the present invention, lead frames having the mounting area 20a′ and the heat radiating area 20a″ surrounding the mounting area 20a′ formed thereon may be arranged in plural. However, the first lead frame 20a having a shape in which the mounting area 20a′ is protruded upwardly so as to be located higher than the heat radiating area 20a″ and the second lead frame 20b having a flat plate may also be provided in plural and be alternately disposed while being spaced apart from each other.

FIG. 4 schematically shows a cross-sectional view of the mounting area 20a′ formed to be protruded upwardly of a lead frame 20. When viewed from above, the lead frame 20 may have a shape in which only the mounting area 20a′ surrounded by the heat radiating area 20a″ maybe upwardly protruded, rather than the overall lead frame 20 being curved and upwardly protruded. That is, the heat radiating area 20a″ except for the mounting area of the light emitting device maybe located lower than the mounting area 20a′ and be coplanarly disposed with respect to the second lead frame 20b. The shape of the lead frame 20 may be formed by press processing the central area of the second lead frame 20b having a flat plate.

Next, referring to FIG. 5, an apparatus for manufacturing the light emitting device package according to the present invention may include a lower mold 50a and a upper mold 50b including cavities having a shape corresponding to that of the molding part 30. A resin composition for manufacturing the molding part 30 is melted and supplied to the cavities formed between the lower and upper molds 50a and 50b to thereby allow for the manufacturing of a light emitting device package structure having a desired shape. Specifically, the lead frame 20 may be disposed between the lower and upper molds 50a and 50b, heated at a high temperature in a state in which the lower surface of the upper mold 50b is pressure-adhered to the upper surface of the lower mold 50a, and melted into a gel phase of a molding material having a certain viscosity to be injected between the lower and upper molds 50a and 50b. The molding part 30 maybe formed to have a height the same as that of the mounting area 20a′, and a void formed in the lower surface of the lead frame 20 corresponding to the mounting area 20a′ may be filled with a molding material, to thereby allow for firmer bonding of the lead frame 20; however, the present invention is not limited thereto. As the molding material forming the molding part 30, a colored molding material having high adhesion, high reliability, high heat-resistant properties, high flame retardancy, and excellent mechanical properties, for example, a molding material having an epoxy molding compound (EMC) and various colors added therein, may be used.

Next, as shown in FIG. 6, after the molding of the molding part 30 having the lead frame 20 adhered thereto is completed, the upper mold 50b and the lower mold 50a are separated into top and bottom sections. The light emitting device 10 maybe disposed on the mounting area 20a′ protruded from an adjacent circumferential area of the lead frame 20 fixed by the molding part 30, and may be wire-bonded to the surface of the lead frame 20 exposed through the molding part 30. As mentioned above, the electrical connection between the lead frame 20 and the light emitting device 10 is not limited thereto, and may be variously modified.

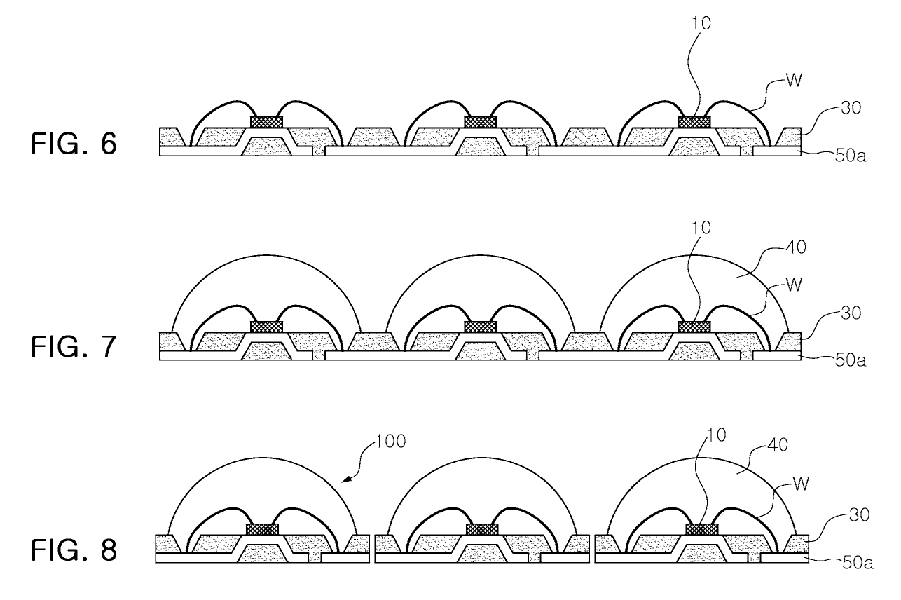

Next, as shown in FIG. 7, the lens part 40 may be disposed on the upper surface of the light emitting device 10. The lens part 40 may have various shapes and, for example, a hemispherical shaped-transparent lens part may be molded by dispensing a resin to or molding the upper surface of the light emitting device 10 with a resin. In this case, prominences and depressions may be formed on the upper surface of the lens part to thereby allow for the increase of light extraction efficiency and the adjustment of the direction of emitted light. The lens part 40 may be made of a resin, and the resin may include any one of epoxy, silicon, strained silicon, a urethane resin, an oxetane resin, acryl, polycarbonate, and polyimide. In addition, prominences and depressions may be formed on the upper surface of the lens part to thereby allow for the increase of light extraction efficiency and the adjustment of the direction of emitted light. The lens part 40 may be made of a material different from that of the molding material 30, and for example, the lens part 40 may be made of a transparent resin so as to allow for the efficient transmission of light and molding part 30 may be made of a high functional colored resin; however, the present invention is not limited thereto.

Next, as shown in FIG. 8, the light emitting device package 100 may be manufactured and provided in plural through the separation of the lead frame 20 for each package unit. As the separation process, a physical process, a chemical cutting process, an etching process or the like may be used. Unlike in the embodiment, in the case in which the pair of lead frames 20a and 20b are alternately disposed while being spaced apart from each other and thus the molding part 30 is present between the plurality of the light emitting device package 100, a process of cutting a metallic martial constituting the lead frame 20 may not be required, whereby the separation process for each package unit may be facilitated. In addition, as in the embodiment of the present invention, a plurality of light emitting device packages may be manufactured and separated in a single process, and also be manufactured as individual light emitting device package units.

As set forth above, according to the embodiments of the invention, there is provided a semiconductor light emitting device having improved reliability through the application of a high functional molding material having high adhesion, high reliability, high heat-resistant properties, high flame retardancy, and excellent mechanical properties.

According to the embodiments of the invention, there is also provided a method of manufacturing a semiconductor light emitting device having a superior heat radiating function through a simple process to thereby allow for improvements in reliability.

While the present invention has been shown and described in connection with the embodiments, it will be apparent to those skilled in the art that modifications and variations can be made without departing from the spirit and scope of the invention as defined by the appended claims.

What is claimed is:

1. A light emitting device package, comprising:
a first lead frame including a mounting area and a heat radiating area surrounding the mounting area, the mounting area being protruded upwardly so as to be located higher than the heat radiating area;
a second lead frame disposed to be spaced apart from the first lead frame;
at least one light emitting device disposed on the mounting area of the first lead frame;
a molding part formed so as to fix the first and second lead frame leads thereto; and
a lens part disposed over the at least one light emitting device and the molding part.

2. The light emitting device package of claim 1, wherein the molding part is formed on upper surfaces of the first and second lead frames, such that an upper surface of the molding part is located lower than an upper surface of the at least one light emitting device.

3. The light emitting device package of claim 1, wherein the molding part is formed to cover a region of a lower surface of the first lead frame corresponding to the mounting area.

4. The light emitting device package of claim 1, wherein the molding part is made of a material different from that of the lens part.

5. The light emitting device package of claim 1, wherein the molding part is made of a colored resin.

6. The light emitting device package of claim 1, wherein the first lead frame includes a mounting area upwardly protruded and having a quadrangular shape, and the heat radiating area of the first lead frame and the second lead frame are coplanarly located.

7. The light emitting device package of claim 1, wherein at least one of the first and second lead frames has at least a part of a lower surface exposed to the outside.

8. The light emitting device package of claim 1, wherein the molding part is formed such that at least parts of upper surfaces of the first and second lead frames are exposed, and the first and second lead frames are wire-bonded to the at least one light emitting device through the exposed surfaces thereof.

9. The light emitting device package of claim 1, wherein at least one of the first and second lead frames includes a through hole formed therein.

10. The light emitting device package of claim 1, further comprising a groove formed by removing a part of the first lead frame in a direction from a side of the first lead frame to the mounting area.

11. The light emitting device package of claim 10, wherein the groove is formed in the side of the first lead frame, opposite to the second lead frame.

12. The light emitting device package of claim 1, further comprising a phosphor layer formed in at least a part of a light emitting surface of the at least one light emitting device.

13. A method of manufacuring a light emitting device package, the method comprising:
press processing at least one of first and second lead frames such that the at least one of first and second lead frames has a mounting area and a heat radiating area surrounding the mounting area formed thereon, the mounting area being protruded upwardly so as to be located higher than the heat radiating area;
forming a molding part in a space between the first and the second lead frames spaced apart from each other to thereby fix the first and the second lead frames thereto;
disposing at least one light emitting device on the mounting area; and
disposing a lens part over the at least one light emitting device.

14. The method of claim 13, wherein at least one of the first and second lead frames has at least a part of a lower surface exposed to the outside.

15. The method of claim 13, wherein the molding part is formed on upper surfaces of the first and second lead frames, such that an upper surface of the molding part is located lower than an upper surface of the at least one light emitting device.

16. The method of claim 13, wherein the molding part is formed to cover a region of a lower surface of the first lead frame, corresponding to the mounting area.

17. The method of claim 13, wherein the molding part is made of a colored resin.

18. The method of claim 13, further comprising wire-bonding the at least one light emitting device to at least one of the first and second lead frames.
